(19) United States
(12) Patent Application Publication
(10) Pub. No.: US 2025/0323062 A1
(43) Pub. Date: Oct. 16, 2025

(54) FABRICATING METHOD OF PACKAGE SUBSTRATE

(71) Applicant: AaltoSemi Inc., Nanjing City (CN)

(72) Inventors: Yin-Ju CHEN, Nanjing City (CN); Yang-Li WU, Nanjing City (CN); Min-Yao CHEN, Nanjing City (CN); Sung-Kun LIN, Nanjing City (CN); Andrew C. CHANG, Nanjing City (CN)

(73) Assignee: AaltoSemi Inc., Nanjing City (CN)

(21) Appl. No.: 19/176,812

(22) Filed: Apr. 11, 2025

(30) Foreign Application Priority Data
Apr. 12, 2024 (CN) 202410438963.3

(51) Int. Cl. H01L 21/48; H01L 21/683

(52) U.S. Cl. CPC H01L 21/486; H01L 21/6835; H01L 21/4853; H01L 2221/68345; H01L 2221/68381

(57) ABSTRACT

A fabricating method of a package substrate is provided, in which two thinnable substrates are laminated onto a carrier to increase the structural thickness during the manufacturing process, so that circuit layers on the substrates can be fabricated with existing processing apparatus. Therefore, the fabricating method may be used for any ultra-thin substrate, and the performance of the existing processing apparatus is sufficient to meet the requirements of the manufacturing process, such that the ability to produce the minimum board thickness may be achieved.

### CROSS-REFERENCE TO RELATED APPLICATIONS

This application claims priority to Chinese Patent Application No. 202410438963.3, filed on Apr. 12, 2024, the entire contents of which are incorporated herein by reference and made a part of this specification.

### BACKGROUND

### 1. Technical Field

The present disclosure relates to a semiconductor packaging process, and more particularly, to a fabricating method of a package substrate that may save production costs.

### 2. Description of Related Art

With the prosperity of electronics industry, electronic products tend to be thin, light, short and small in form, and are being developed toward high performance, high functionality and high speed in function. Therefore, in order to meet the high integration and miniaturization requirements of semiconductor devices, package substrates designed as thinnable, low warpage, and high-density wiring are often employed in the packaging process.

However, in the conventional fabricating method for package substrates, there is a risk of damage of the existing apparatus to the substrate thickness requirements, thus limiting processing capability for thinner substrates. Therefore, when producing package substrates that conform to thin, low warpage, and high-density wiring designs, specialized apparatus with special specifications is required, making it difficult to reduce production costs.

Therefore, how to overcome the problems of the prior art mentioned above has become an urgent issue to be solved.

### SUMMARY

In view of the deficiencies of the prior art mentioned above, the present disclosure provides a method of fabricating a package substrate, the method comprises: providing a plurality of carriers, wherein substrates are formed on opposite sides of each of the carriers respectively; forming circuit portions via the substrates to obtain a plurality of batches of carrier structures; bonding support boards onto the circuit portions of one batch of the carrier structures; removing the carrier of the carrier structure bonded with the support boards to form a plurality of substrate structures bonded with the support boards; bonding the substrate structures onto the circuit portions on opposite sides of another batch of the carrier structures via the support boards of the substrate structures; removing the carrier of the another batch of the carrier structures bonded to the substrate structures and the support boards to obtain a plurality of multi-board structures; forming wiring layers electrically connected to the circuit portions via the substrates of the multi-board structure; and removing the support board.

In the foregoing method, each of the substrates comprises a core layer and a first metal layer and a second metal layer formed on two opposite surfaces of the core layer respectively. For example, each of the circuit portions comprises a circuit layer formed via the second metal layer, and at least one conductive pillar disposed in the core layer and electrically connected to the circuit layer and the wiring layer. Furthermore, the at least one conductive pillar is conical, and a top end diameter thereof is greater than a bottom end diameter thereof, and a density of the circuit layer on the core layer is greater than a density of the wiring layer on the core layer. Alternatively, the wiring layer is formed via the first metal layer.

The foregoing method further comprises forming solder mask layers on the substrates, wherein the wiring layers are exposed from surfaces of the solder mask layers. For example, the support board is made of a thermal release film. Further, when a dissociation temperature of the support board is lower than a curing temperature of the solder mask layers, the support board is removed first, and then the solder mask layers are cured. Alternatively, when a dissociation temperature of the support board is higher than a curing temperature of the solder mask layers, the solder mask layers are cured first, and then the support board is removed.

As may be seen from the above, the fabricating method of the package substrate of the present disclosure is mainly to laminate two thinnable substrates onto a carrier to increase the structural thickness during the manufacturing process, so that all existing processing apparatus can fabricate the carrier structures. Therefore, the fabricating method of the present disclosure can be used for any ultra-thin substrate, and the performance of the existing processing apparatus is sufficient to meet the requirements of the manufacturing process, such that the ability to produce the smallest board thickness may be achieved.

Furthermore, by using the carrier and the support board, any ultra-thin substrate in the form of a core substrate can be fabricated into a package substrate.

Also, in order to ensure that the flatness of the thinner substrate structure meets the requirements and to prevent the substrate structure from warpage problem, a plurality of carrier structures are designed in batches to fabricate one batch of the carrier structures into substrate structures, and the substrate structures are bonded to another batch of carrier structures to maintain the required thickness during the overall manufacturing process. Therefore, the substrate structure can be prevented from warpage problem, and the substrate structure can be prevented from damaged caused by manual handling or transferring.

In addition, the fabricating method of the present disclosure employs conical through vias to fabricate the conductive pillars, so that the top end diameter thereof is greater than the bottom end diameter thereof. Therefore, the density of the circuit layer on the core layer is greater than the density of the wiring layer on the core layer, which benefits coupling pins of the required electronic devices.

### BRIEF DESCRIPTION OF THE DRAWINGS

The exemplary embodiments herein may be better understood by referring to the following description in conjunction with the accompanying drawings in which like reference numerals indicate identically or functionally similar elements, of which:

FIG. 1A-1, FIG. 1B, FIG. 1C, FIG. 1D, FIG. 1E, FIG. 1F, FIG. 1G and FIG. 1H are schematic cross-sectional views illustrating a fabricating method of an exemplary package substrate of the present disclosure.

FIG. 1A-2 is a schematic cross-sectional view of another exemplary aspect of a substrate of FIG. 1A-1.

FIG. 2 is a schematic cross-sectional view of a following process of FIG. 1H.

FIG. 3A to FIG. 3B are schematic cross-sectional views of forming straight cylindrical through vias and conductive pillars.

FIG. 4A to FIG. 4B are schematic cross-sectional views of forming biconical through vias and conductive pillars.

FIG. 5A to FIG. 5B are schematic cross-sectional views of forming conical through vias and conductive pillars of the present disclosure.

### DETAILED DESCRIPTION

Implementations of the present disclosure are illustrated below by embodiments. Those skilled in the art may easily understand other advantages and effects of the present disclosure from the content disclosed in this specification.

It should be noted that the structures, proportions, sizes, etc. depicted in the drawings appended to this specification are used in coordination with the content disclosed in the specification to facilitate understanding for those skilled in the art. They are not intended to limit specific conditions of implementing the techniques and methods of this disclosure. Without affecting the effects created and the purposes achieved by this disclosure, any modification, change, or adjustments in structures, proportions, or sizes shall still fall within the scope of the technical content disclosed herein. Meanwhile, terms such as “on,” “first,” “second,” “third,” “a,” “one,” and the like cited in this specification are only for illustrating clearly and are not used to limit the implementable scope of the present disclosure. Without substantial change in the technical content, changes or adjustments of their relative relationships shall also be regarded as within the implementable scope of the present disclosure.

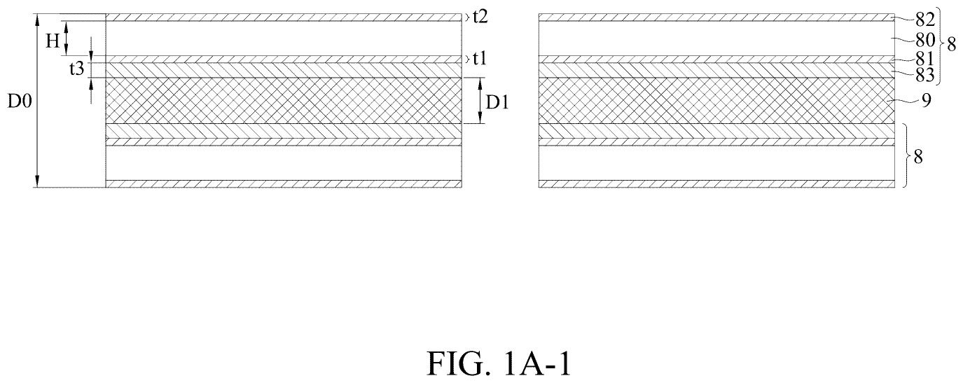

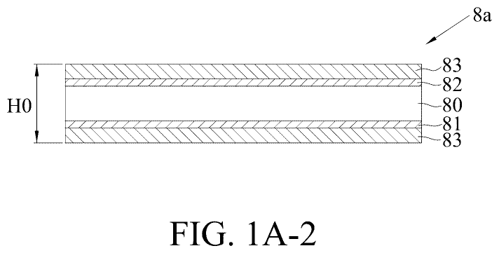

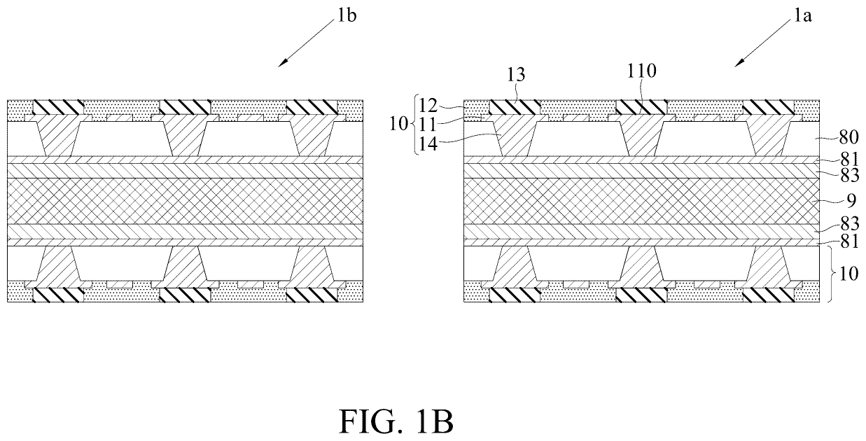

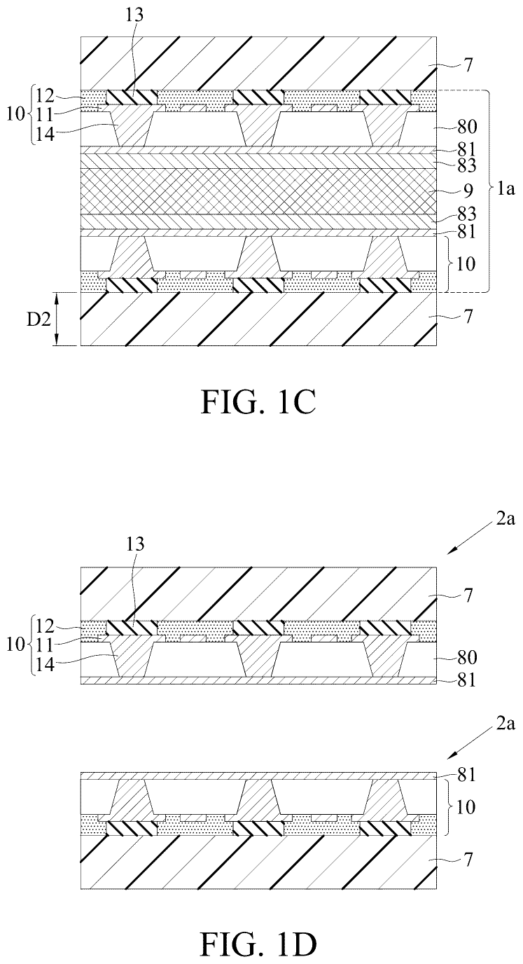

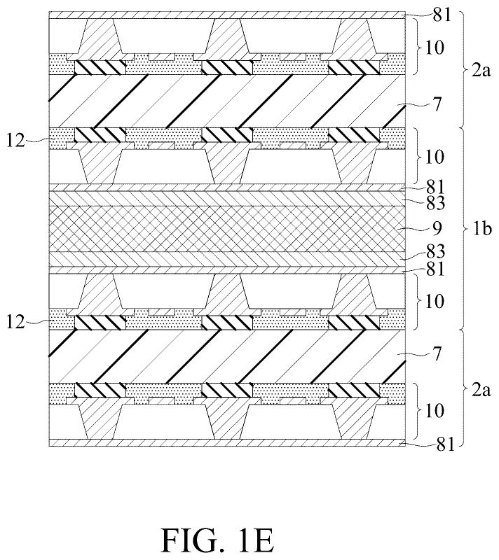

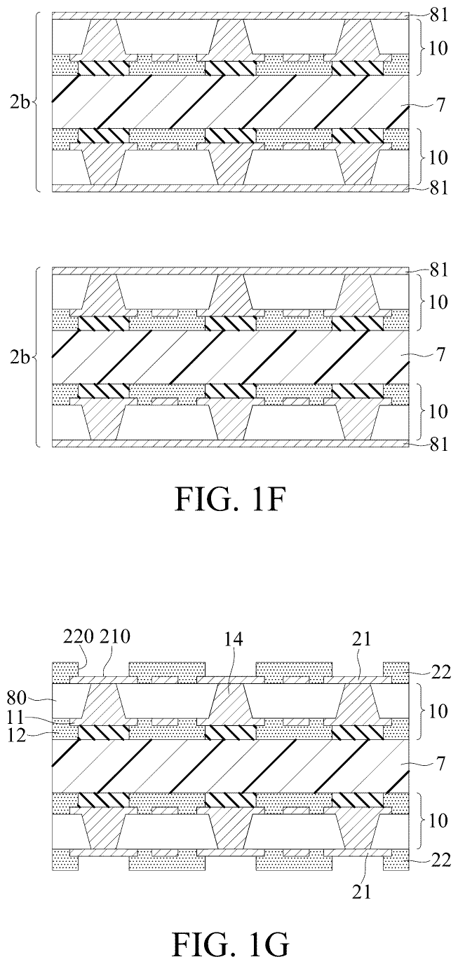

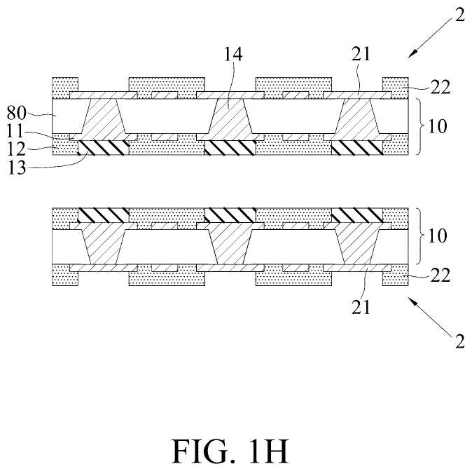

FIG. 1A-1, FIG. 1B, FIG. 1C, FIG. 1D, FIG. 1E, FIG. 1F, FIG. 1G and FIG. 1H are schematic cross-sectional views illustrating a fabricating method of a package substrate 2 of the present disclosure.

As shown in FIG. 1A-1, a plurality of carriers 9 are provided, and a substrate 8 is symmetrically formed on opposite sides of each of the carriers 9.

In an embodiment, the carrier 9 is a temporary carrier board with a thickness D1 of at least 140 microns (μm), and the carrier 9 may be made of any material with a toughness and a glass transition temperature (Tg) higher than that of the substrate 8, such as prepreg (PP), flame resistant 4 (FR-4), or thermal release film.

Furthermore, the substrate 8 is a core board with metal layers on opposite sides, such as a copper foil substrate, and a first metal layer 81 and a second metal layer 82 such as copper layers are formed on the opposite surfaces of a core layer 80 respectively, and a third metal layer 83 made of such as copper is formed on the first metal layer 81, such that the third metal layer 83 is laminated on the carrier 9, so that the second metal layer 82 is exposed to outer side. Also, the core layer 80 may be made of polybenzoxazole (PBO), polyimide (PI), prepreg (PP), or other dielectric materials.

Also, the thickness H of the core layer 80 is, for example, 30 microns, so that the overall minimum structural thickness D0 in FIG. 1A-1 is at least 200 microns, and the thickness t1 of the first metal layer 81 and the thickness t2 of the second metal layer 82 are less than the thickness t3 of the third metal layer 83. For example, the thickness t1 of the first metal layer 81 and the thickness t2 of the second metal layer 82 are both 3 microns, and the thickness t3 of the third metal layer 83 is 18 microns.

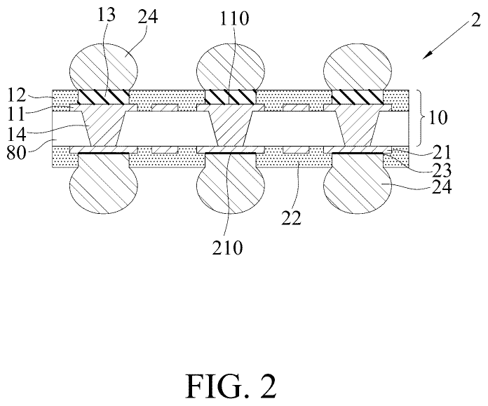

In addition, when fabricating the substrate 8, a thicker metal layer (such as the third metal layer 83) may also be formed on the second metal layer 82 first, to form a symmetrical structure 8a as shown in FIG. 1A-2, the thickness H0 of which may be at least 72 microns. After the substrate 8 is bonded to the carrier 9, the thicker metal layer (such as the third metal layer 83) on the second metal layer 82 is removed, so that the second metal layer 82 is exposed to the outer side, and the overall minimum structural thickness D0 in FIG. 1A-1 is greater than 200 microns, which meets the processing requirements of the process apparatus. For example, stacking the substrate 8 on each of the opposite sides of the carrier 9 using a bolt clamp, a fixing tool, or a high-precision bonding tool can prevent the substrate 8 from mismatch problem during stacking.

As shown in FIG. 1B, a patterned wiring process is performed to the second metal layer 82 to form a circuit portion 10 on each of the core layers 80, so as to obtain a plurality of batches of carrier structures 1a, 1b.

In an embodiment, the circuit portion 10 comprises a circuit layer 11 formed on the core layer 80, at least one conductive pillar 14 disposed in the core layer 80 and electrically connected to the circuit layer 11, and an insulating layer 12 formed on the core layer 80 and covering the circuit layer 11. For example, the insulating layer 12 may be used as a solder mask layer, and the circuit layer 11 is exposed from the solder mask layer to serve as electrical contact pads 110. Further, a surface treatment layer 13 made of nickel, gold, or other metal materials may be formed on the electrical contact pads 110.

Furthermore, the circuit portion 10 is fabricated by electroplating metal (such as copper) or other methods employing build-up process. For example, a plurality of through vias are formed by laser on the core layer 80 first, and then copper is electroplated on the core layer 80 and in the through vias to integrally form the circuit layer 11 and the conductive pillars 14.

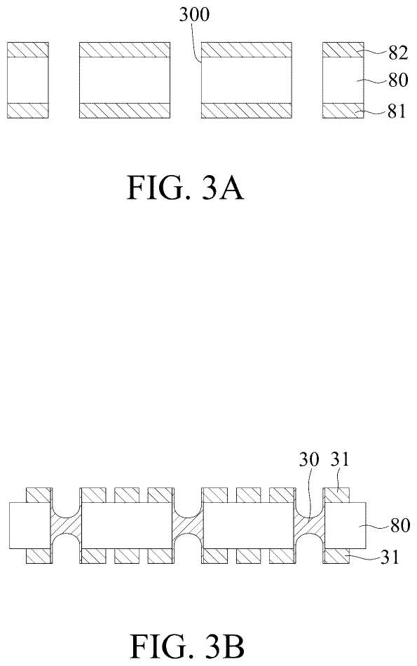

Also, the through vias formed by laser in the present disclosure are single-conical through vias, which can avoid common unfilled up through vias defects of the straight cylindrical through vias formed by conventional machine drilling and avoid bubbles defects caused by electroplating of the biconical through vias. In particular, as shown in FIG. 3A to FIG. 3B, if a plurality of straight cylindrical through vias 300 penetrating through the core layer 80, the first metal layer 81 and the second metal layer 82 are formed first, and then circuit layers 31 are formed by the first metal layer 81 and the second metal layer 82, and conductive pillars 30 are formed in the through vias 300 and electrically connected to the circuit layers 31, defects that the through vias 300 are not filled up with copper are prone to occur.

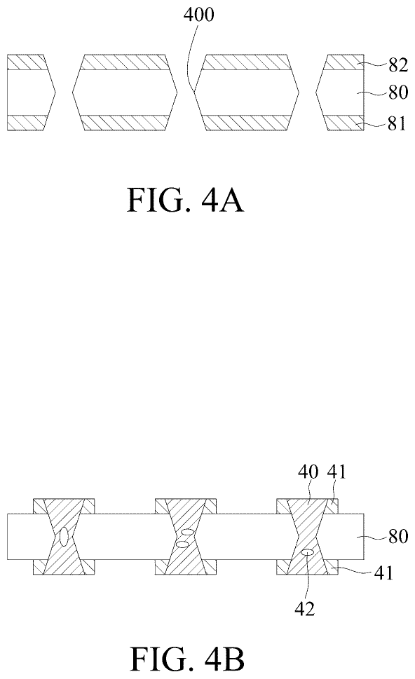

As shown in FIG. 4A to FIG. 4B, if via-forming operation is performed first on the first metal layer 81 and the second metal layer 82 of the core layer 80 to form a plurality of interconnected biconical through vias 400, and then circuit layers 41 are formed by the first metal layer 81 and the second metal layer 82, and conductive pillars 40 are formed in the through vias 400 and electrically connected to the circuit layers 41, wherein bubbles 42 are prone to be formed in the conductive pillars 40.

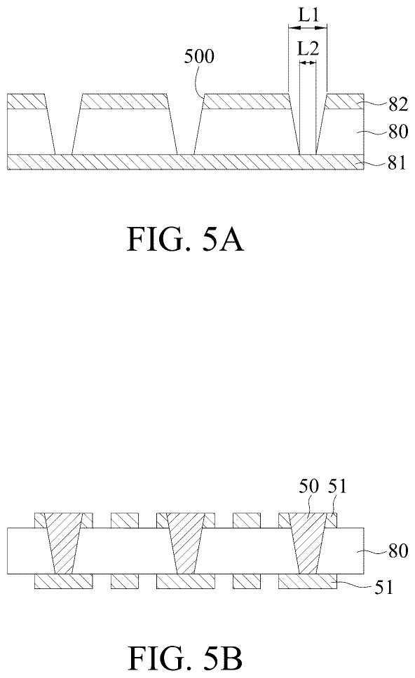

On the contrary, as shown in FIG. 5A to FIG. 5B, a plurality of conical through vias 500 penetrating through the core layer 80 and the second metal layer 82 are formed first in the present disclosure, and the top end diameter L1 thereof is greater than the bottom end diameter L2 thereof. Afterwards, circuit layers 51 are formed by the first metal layer 81 and the second metal layer 82, and conductive pillars 50 are formed in the through vias 500 and electrically connected to the circuit layers 51, wherein the through vias 500 are filled with copper to form solid conductive pillars 50 without bubbles.

Therefore, in an embodiment, the conical conductive pillars 14 are fabricated in a preferred manner as shown in FIG. 5A to FIG. 5B, so that the shape of the through vias 500 is the same as the shape of the conductive pillars 14. That is, the conical through vias 500 are conducive to the electroplating filling operation and the reduction of the occurrence of electroplating failure (as shown in FIG. 3B and FIG. 4B), and are also conducive to the reliability performance during the following packaging operation.

As shown in FIG. 1C, a support board 7 is bonded onto the insulating layer 12 of each of the circuit portions 10 of one batch of the carrier structures 1a.

In an embodiment, the support board 7 is a temporary support board, and the thickness D2 of the support board 7 is greater than or equal to 140 microns (μm), and the support board 7 may be made of any material with a toughness and a glass transition temperature (Tg) higher than that of the substrate 8, such as PP, FR-4, or thermal release film. For example, the support board 7 may be laminated onto each side of the carrier structure la by vacuum lamination, roller lamination, lamination tools, or the like.

As shown in FIG. 1D, the carrier 9 is removed, and then the third metal layer 83 is removed to form a substrate structure 2a bonded onto the support board 7.

As shown in FIG. 1E, the support boards 7 of the plurality of substrate structures 2a are bonded to the insulating layers 12 of the circuit portions 10 on opposite sides of another batch of the carrier structures 1b.

In an embodiment, the substrate structure 2a is stacked on each of the opposite sides of the carrier structure 1b by using a bolt clamp, a fixing tool, or a high-precision bonding tool, which can prevent the substrate structure 2a from mismatch problem during stacking.

As shown in FIG. 1F, the carrier 9 of the another batch of the carrier structures 1b that has bonded to the substrate structures 2a and the support boards 7 is removed, and then the third metal layers 83 of the another batch of the carrier structures 1b are removed to obtain a plurality of multi-board structures 2b, and the upper outer surfaces of the opposite sides of the support board 7 are the first metal layers 81.

As shown in FIG. 1G, a patterned wiring process is performed on each of the first metal layers 81 of the multi-board structure 2b to form a wiring layer 21 electrically connected to the conductive pillars 14 on each of the core layers 80.

In an embodiment, the wiring layer 21 is made of copper, such as employing a redistribution layer (RDL) specification.

Furthermore, a solder mask layer 22 may be formed on each of the core layers 80, and the wiring layer 21 is exposed from the surface of the solder mask layer 22 to serve as electrical contacts 210. For example, a plurality of openings 220 are formed on the solder mask layer 22 and expose the wiring layer 21.

As shown in FIG. 1H, the support board 7 is removed, and the solder mask layers 22 and the insulating layers 12 are thermally cured to obtain a plurality of package substrates 2.

In an embodiment, when the support board 7 is made of a thermal release film, the temperature at which it decomposes and detaches from the substrate structure 2a (i.e., the dissociation temperature) may be higher or lower than the post-cure temperature or curing temperature of the solder mask layer 22 depending on requirements. Therefore, when the dissociation temperature of the support board 7 (such as 120° C.) is lower than the curing temperature of the solder mask layer 22 (such as 160° C.), the support board 7 is heated (such as 120° C.) first to remove the support board 7, and then the solder mask layer 22 is heated (such as 160° C.) and cured. In other embodiments, when the dissociation temperature of the support board 7 (such as 190° C.) is higher than the curing temperature of the solder mask layer 22 (such as 160° C.), the solder mask layer 22 is heated and cured first, and then the support board 7 is heated to remove the support board 7.

In addition, in the following process, as shown in FIG. 2, a surface treatment layer 23 may be formed on the electrical contacts 210 to bond to solder balls 24 electrically connected to the wiring layer 21, so that electronic devices (not shown) such as semiconductor chips, passive components, silicon interposers, circuit boards, or other components may be connected to the package substrate 2 by the solder balls 24. It should be understood that, as shown in FIG. 2, solder balls 24 may also be bonded onto the electrical contact pads 110 on the circuit layer 11.

In summary, the fabricating method of the present disclosure mainly increases the structural thickness during the manufacturing process by laminating two thin substrates 8 onto a carrier 9. As shown in FIG. 1A-1, the overall minimum structural thickness D0 is at least 200 microns, so that existing processing apparatus can fabricate the carrier structures 1a, 1b. Therefore, the fabricating method of the present disclosure may be used for any ultra-thin substrate 8, and the performance of the existing processing apparatus is sufficient to meet the process requirements, such that the ability to produce the minimum board thickness may be achieved.

Furthermore, by using the carrier 9 and the support board 7, any ultra-thin substrate 8 in the form of a core substrate may be fabricated to the package substrate 2.

Also, in order to ensure that the flatness of the thinner substrate structure 2a meets the requirements and to prevent the substrate structure 2a from warpage problem, a plurality of carrier structures 1a, 1b are designed in batches to fabricate one batch of the carrier structures 1a into substrate structures 2a, and the substrate structures 2a are bonded to another batch of the carrier structures 1b, as shown in FIG. 1E, to maintain the required thickness during the overall manufacturing process. Therefore, the substrate structure 2a can be prevented from warpage problem, and the substrate structure 2a can be prevented from damaged caused by manual handling or transferring.

In addition, the conductive pillars 14 are fabricated by employing conical through vias 500 in the fabricating method of the present disclosure, so that the top end diameter L1 thereof is greater than the bottom end diameter L2 thereof. Therefore, the density of the electrical contact pads 110 is greater than the density of the electrical contacts 210, that is, the density of the circuit layer 11 on the core layer 80 is greater than the density of the wiring layer 21 on the core layer 80, which benefits coupling to the pins of required electronic devices (not shown) such as semiconductor chips, packaging components, memories, and the like.

The above embodiments are used to exemplarily illustrate the principles and effects of the present disclosure, but are not used to limit the present disclosure. Anyone skilled in the art may perform modifications to the above embodiments without departing from the spirit and scope of the present disclosure. Therefore, the scope claimed of the present disclosure should be defined by the following claims.

What is claimed is:

1. A method of fabricating a package substrate, comprising:
providing a plurality of carriers, wherein substrates are formed on opposite sides of each of the carriers respectively;
forming circuit portions via the substrates to obtain a plurality of batches of carrier structures;
bonding support boards onto the circuit portions of one batch of the carrier structures;
removing the carrier of the carrier structure bonded with the support boards to form a plurality of substrate structures bonded with the support boards;
bonding the substrate structures onto the circuit portions on opposite sides of another batch of the carrier structures via the support boards of the substrate structures;
removing the carrier of the another batch of the carrier structures bonded to the substrate structures and the support boards to obtain a plurality of multi-board structures;
forming wiring layers electrically connected to the circuit portions via the substrates of the multi-board structure; and
removing the support board.

2. The method of claim 1, wherein each of the substrates comprises a core layer and a first metal layer and a second metal layer formed on two opposite surfaces of the core layer respectively.

3. The method of claim 2, wherein each of the circuit portions comprises a circuit layer formed via the second metal layer, and at least one conductive pillar disposed in the core layer and electrically connected to the circuit layer and the wiring layer.

4. The method of claim 3, wherein the at least one conductive pillar is conical, and a top end diameter thereof is greater than a bottom end diameter thereof.

5. The method of claim 4, wherein a density of the circuit layer on the core layer is greater than a density of the wiring layer on the core layer.

6. The method of claim 2, wherein the wiring layer is formed via the first metal layer.

7. The method of claim 1, further comprising forming solder mask layers on the substrates, wherein the wiring layers are exposed from surfaces of the solder mask layers.

8. The method of claim 7, wherein the support board is made of a thermal release film.

9. The method of claim 8, wherein when a dissociation temperature of the support board is lower than a curing temperature of the solder mask layers, the support board is removed first, and then the solder mask layers are cured.

10. The method of claim 8, wherein when a dissociation temperature of the support board is higher than a curing temperature of the solder mask layers, the solder mask layers are cured first, and then the support board is removed.
